(19) United States
(12) Patent Application Publication
(10) Pub. No.: US 2026/0047054 A1
(43) Pub. Date: Feb. 12, 2026

(54) COMPOSITE ELECTROMAGNETIC WAVE-ABSORBING MATERIAL AND PREPARATION METHOD THEREFOR

(71) Applicant: Hefei Zhongyin New Materials Co., Ltd, Hefei (CN)

(72) Inventors: Zhongcai Yuan, Hefei (CN); Liuyuan Man, Hefei (CN)

(21) Appl. No.: 19/250,063

(22) Filed: Jun. 26, 2025

(30) Foreign Application Priority Data
Aug. 12, 2024 (CN) 202411096297.6

(51) Int. Cl. H05K 9/00; B22F 1/00; B22F 1/145

(52) U.S. Cl. CPC H05K 9/0083; B22F 1/09; B22F 1/147; B22F 2302/25

(57) ABSTRACT

A composite electromagnetic wave-absorbing material and preparation method therefor are provided. The composite electromagnetic wave-absorbing material includes following raw materials: magnetite powder, nickel powder, copper powder, samarium oxide, gadolinium oxide, cerium oxide, carbon black powder, graphite powder, epoxy resin, barium titanate powder, antioxidant, curing agent, diluent and leveling agent. Ferrite wave-absorbing materials are used as matrixes to be compounded with nickel powder, copper powder, graphite powder, carbon black and barium titanate, and doped with mixed rare earth oxides through combination of samarium oxide, gadolinium oxide and cerium oxide to thereby obtain the composite electromagnetic wave-absorbing material which combines magnetic loss characteristics of magnetite powder, ferromagnetic behavior of nickel powder and conductivity of copper powder, helping to achieve good electromagnetic wave-absorbing performance. By introducing graphite powder, carbon black powder and barium titanate powder as fillers and doping rare earth, wave-absorbing characteristics of the composite electromagnetic wave-absorbing material are improved.

### CROSS-REFERENCE TO RELATED APPLICATION

This application claims priority to Chinese Patent Application No. 202411096297.6, filed on Aug. 12, 2024, which is herein incorporated by reference in its entirety.

### TECHNICAL FIELD

The disclosure relates to the technical field of electromagnetic wave-absorbing materials, and more particularly to a composite electromagnetic wave-absorbing material and a preparation method therefor.

### BACKGROUND

Electromagnetic wave-absorbing material refers to a kind of material that can absorb or greatly weaken energy of electromagnetic waves incident on its surface, thereby reducing interference of the electromagnetic waves. In engineering applications, in addition to requiring a wave-absorbing material to have a high absorption ratio for the electromagnetic waves in a wide frequency band, the wave-absorbing material is also required to have light weight, temperature resistance, moisture resistance, corrosion resistance and other properties. Electromagnetic radiation causes direct and indirect damage to human bodies through thermal effects, non-thermal effects and cumulative effects. Studies have confirmed that a ferrite wave-absorbing material has a best performance, featuring high absorption frequency band, high absorption ratio and thin matching thickness. Applying the ferrite wave-absorbing material to electronic equipment can absorb leaky electromagnetic radiation, thereby achieving an objective of eliminating electromagnetic interference.

The ferrite wave-absorbing material is prepared by dispersing ferrite in binder of organic polymer materials, and adding some other additives at the same time. However, with an increasing demand of application fields, performance requirements of the electromagnetic wave-absorbing material are also improved, so how to improve comprehensive performance of a ferrite electromagnetic wave-absorbing materials is a problem urgent to be solved. Therefore, the disclosure provides a composite electromagnetic wave-absorbing material and a preparation method therefor to solve the problems in related art.

### SUMMARY

To solve aforementioned problem, the disclosure aims to provide a composite electromagnetic wave-absorbing material and a preparation method therefor. The disclosure dopes rare earth elements and combines various materials to prepare the composite electromagnetic wave-absorbing material, so that comprehensive performance of the composite electromagnetic wave-absorbing material is improved, and the problem in related art can be solved.

To achieve objectives of the disclosure, technical solutions used by the disclosure are as follows. The composite electromagnetic wave-absorbing material provided by an embodiment of the disclosure includes the following raw materials in parts by weight: 50-60 parts of magnetite powder, 5-8 parts of nickel powder, 5-8 parts of copper powder, 2-4 parts of samarium oxide, 2-4 parts of gadolinium oxide, 2-4 parts of cerium oxide, 5-7 parts of carbon black powder, 8-15 parts of graphite powder, 20-30 parts of epoxy resin, 5-7 parts of barium titanate powder, 1-2 parts of antioxidant, 15-20 parts of curing agent, 1-2 parts of diluent and 1-2 parts of leveling agent.

In an embodiment, the composite electromagnetic wave-absorbing material includes the following raw materials in parts by weight: 60 parts of the magnetite powder, 5 parts of the nickel powder, 5 parts of the copper powder, 2 parts of the samarium oxide, 2 parts of the gadolinium oxide, 2 parts of the cerium oxide, 7 parts of the carbon black powder, 8 parts of the graphite powder, 20 parts of the epoxy resin, 7 parts of the barium titanate powder, 2 parts of the antioxidant, 15 parts of the curing agent, 2 parts of the diluent and 2 parts of the leveling agent.

In an embodiment, the composite electromagnetic wave-absorbing material includes the following raw materials in parts by weight: 50 parts of the magnetite powder, 8 parts of the nickel powder, 8 parts of the copper powder, 4 parts of the samarium oxide, 4 parts of the gadolinium oxide, 4 parts of the cerium oxide, 5 parts of the carbon black powder, 15 parts of the graphite powder, 30 parts of the epoxy resin, 5 parts of the barium titanate powder, 1 part of the antioxidant, 20 parts of the curing agent, 1 part of the diluent and 1 part of the leveling agent.

In an embodiment, the samarium oxide, the gadolinium oxide, the cerium oxide and the barium titanate powder are all in powder form.

In an embodiment, the antioxidant is a phenolic antioxidant, the curing agent is an aromatic amine curing agent diethyl toluene diamine, the diluent is polyol glycidyl ether, the leveling agent is silicone oil, and the epoxy resin is bisphenol A based epoxy resins.

The preparation method for the composite electromagnetic wave-absorbing material provided by another embodiment of the disclosure includes the following steps:
step 1, preparing materials, including:
   weighing, according to a formula, 50-60 parts of the magnetite powder, 5-8 parts of the nickel powder, 5-8 parts of the copper powder, 2-4 parts of the samarium oxide, 2-4 parts of the gadolinium oxide, 2-4 parts of the cerium oxide, 5-7 parts of the carbon black powder, 8-15 parts of the graphite powder, 20-30 parts of the epoxy resin, 5-7 parts of the barium titanate powder, 1-2 parts of the antioxidant, 15-20 parts of the curing agent, 1-2 parts of the diluent and 1-2 parts of the leveling agent;
step 2, mixing wave-absorbing magnetic materials, including:
   grinding, by using an ultra-fine powder grinding machine, the magnetite powder, the nickel powder and the copper powder individually to obtain ground magnetite powder, ground nickel powder and ground copper powder, adding the ground magnetite powder, the ground nickel powder and the ground copper powder into a dry powder mixer to obtain a first powder mixture, adding the graphite powder, the carbon black powder and the barium titanate powder to the first powder mixture to thereby obtain a second powder mixture, and stirring the second powder mixture to obtain a mixed wave-absorbing magnetic material;
step 3, mixing rare earth materials, including:
   drying the samarium oxide, the gadolinium oxide and the cerium oxide in a vacuum drying oven to obtain dried samarium oxide, dried gadolinium oxide and dried cerium oxide, and mixing, by the dry powder mixer, the dried samarium oxide, the dried gadolinium oxide and the dried cerium oxide to obtain a mixed rare earth oxide material; and
step 4, preparing the composite electromagnetic wave-absorbing material, including:
   stirring and mixing the epoxy resin and the curing agent in a heated environment to obtain a first mixture, adding the diluent to the first mixture to obtain a second mixture, continuing to stir the second mixture to obtain a mixed matrix, adding the mixed wave-absorbing magnetic material prepared in the step 2 and the mixed rare earth oxide material prepared in the step 3 to the mixed matrix to thereby obtain a third mixture, stirring the third mixture for mixing, and adding the antioxidant and the leveling agent to the third mixture for ultrasonic dispersion during stirring the third mixture, to thereby obtain the composite electromagnetic wave-absorbing material.

In an embodiment, in the step 2, particle sizes of the magnetite powder, the nickel powder and the copper powder are controlled in a range of 2 micrometers (μm) to 5 μm by using the ultra-fine powder grinding machine.

In an embodiment, the samarium oxide, the gadolinium oxide and the cerium oxide are dried by vacuum drying at a temperature in a range of 90 Celsius degrees (° C.) to 120° C. for 10 minutes (min) to 20 min.

In an embodiment, in the step 4, a temperature of the heated environment is in a range of 60° C. to 80° C.

The disclosure has the following beneficial effects. The composite electromagnetic wave-absorbing material provided by the disclosure uses ferrite wave-absorbing materials as matrixes. The ferrite wave-absorbing materials are compounded with the nickel powder, the copper powder, the graphite powder, the carbon black and the barium titanate, and are doped with mixed rare earth oxides through a combination of the samarium oxide, the gadolinium oxide and the cerium oxide to thereby obtain the composite electromagnetic wave-absorbing material. The composite electromagnetic wave-absorbing material combines magnetic loss characteristics of the magnetite powder, ferromagnetic behavior of the nickel powder and conductivity of the copper powder, helping to achieve good electromagnetic wave-absorbing performance. By introducing the graphite powder, the carbon black powder and barium titanate powder as fillers, performance of the composite electromagnetic wave-absorbing material is improved. Then, by doping rare earth, wave-absorbing characteristics of the composite electromagnetic wave-absorbing material are improved, to thereby comprehensively improve the performance of the composite electromagnetic wave-absorbing material and mFieet higher performance requirements.

### BRIEF DESCRIPTION OF DRAWING

FIGURE illustrates a flowchart of a preparation method for a composite electromagnetic wave-absorbing material according to an embodiment of the disclosure.

### DETAILED DESCRIPTION OF EMBODIMENTS

To deepen understanding of the disclosure, the disclosure will be further described with reference to specific embodiments. Embodiments of the disclosure are merely to interpret the disclosure, not to limit a scope of protection of the disclosure.

Raw materials used by the following embodiments are all available through commercial means.

### Embodiment 1

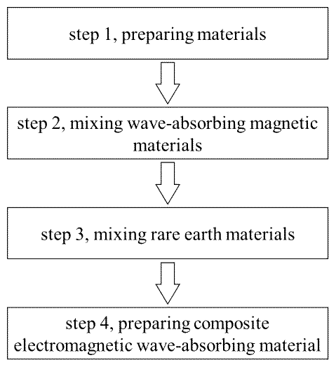

As illustrated in FIG. 1, a composite electromagnetic wave-absorbing material provided by the embodiment includes the following raw materials in parts by weight: 60 parts of magnetite powder, 5 parts of nickel powder, 5 parts of copper powder, 2 parts of samarium oxide, 2 parts of gadolinium oxide, 2 parts of cerium oxide, 7 parts of carbon black powder, 8 parts of graphite powder, 20 parts of epoxy resin, 7 parts of barium titanate powder, 2 parts of antioxidant, 15 parts of curing agent, 2 parts of diluent and 2 parts of leveling agent. The samarium oxide, the gadolinium oxide, the cerium oxide and the barium titanate powder are all in powder form.

The antioxidant is a phenolic antioxidant, specifically 2,6-di-tert-butylphenol (BHT). The curing agent is an aromatic amine curing agent diethyl toluene diamine. The diluent is polyol glycidyl ether. The leveling agent is silicone oil. The epoxy resin is bisphenol A based epoxy resin.

A preparation method for the composite electromagnetic wave-absorbing material provided by the embodiment includes the following step 1 through step 4.

Step 1, materials are prepared.

According to a formula, 60 parts of the magnetite powder, 5 parts of the nickel powder, 5 parts of the copper powder, 2 parts of the samarium oxide, 2 parts of the gadolinium oxide, 2 parts of the cerium oxide, 7 parts of the carbon black powder, 8 parts of the graphite powder, 20 parts of the epoxy resin, 7 parts of the barium titanate powder, 2 parts of the antioxidant, 15 parts of the curing agent, 2 parts of the diluent and 2 parts of the leveling agent are weighed.

Step 2, wave-absorbing magnetic materials are mixed.

The magnetite powder, the nickel powder and the copper powder are individually ground by using an ultra-fine powder grinding machine to obtain ground magnetite powder, ground nickel powder and ground copper powder. The ground magnetite powder, the ground nickel powder and the ground copper powder are added into a dry powder mixer to obtain a first powder mixture. The graphite powder, the carbon black powder and the barium titanate powder are added to the first powder mixture to thereby obtain a second powder mixture. The second powder mixture is stirred to obtain a mixed wave-absorbing magnetic material. Particle sizes of the magnetite powder, the nickel powder and the copper powder are controlled at 5 μm by using the ultra-fine powder grinding machine.

Step 3, rare earth materials are mixed.

The samarium oxide, the gadolinium oxide and the cerium oxide are dried in a vacuum drying oven to obtain dried samarium oxide, dried gadolinium oxide and dried cerium oxide. The dried samarium oxide, the dried gadolinium oxide and the dried cerium oxide are mixed by the dry powder mixer to obtain a mixed rare earth oxide material. Parameters of the vacuum drying oven include 120° C. of a temperature, and 10 min of a drying duration.

Step 4, the composite electromagnetic wave-absorbing material is prepared.

The epoxy resin and the curing agent are mixed and stirred in a heated environment to obtain a first mixture. A temperature of the heated environment is 80° C. The diluent is added to the first mixture to obtain a second mixture. The second mixture is continuously stirred to obtain a mixed matrix. The mixed wave-absorbing magnetic material prepared in the step 2 and the mixed rare earth oxide material prepared in the step 3 are added to the mixed matrix to thereby obtain a third mixture. The third mixture is stirred for mixing. The antioxidant and the leveling agent are added to the third mixture for ultrasonic dispersion during stirring the third mixture, to thereby obtain the composite electromagnetic wave-absorbing material.

In the embodiment, other parameters of the embodiment are the same as those of embodiment 3.

### Embodiment 2

As illustrated in FIG. 1, a composite electromagnetic wave-absorbing material provided by the embodiment includes the following raw materials in parts by weight: 50 parts of magnetite powder, 8 parts of nickel powder, 8 parts of copper powder, 4 parts of samarium oxide, 4 parts of gadolinium oxide, 4 parts of cerium oxide, 5 parts of carbon black powder, 15 parts of graphite powder, 30 parts of epoxy resin, 5 parts of barium titanate powder, 1 part of antioxidant, 20 parts of curing agent, 1 part of diluent and 1 part of leveling agent. The samarium oxide, the gadolinium oxide, the cerium oxide and the barium titanate powder are all in powder form. The antioxidant is a phenolic antioxidant. The curing agent is an aromatic amine curing agent diethyl toluene diamine. The diluent is polyol glycidyl ether. The leveling agent is silicone oil. The epoxy resin is bisphenol A based epoxy resins.

A preparation method for the composite electromagnetic wave-absorbing material provided by the embodiment includes the following step 1 through step 4.

Step 1, materials are prepared.

According to a formula, 50 parts of the magnetite powder, 8 parts of the nickel powder, 8 parts of the copper powder, 4 parts of the samarium oxide, 4 parts of the gadolinium oxide, 4 parts of the cerium oxide, 5 parts of the carbon black powder, 15 parts of the graphite powder, 30 parts of the epoxy resin, 5 parts of the barium titanate powder, 1 part of the antioxidant, 20 parts of the curing agent, 1 part of the diluent and 1 part of the leveling agent are weighed.

Step 2, wave-absorbing magnetic materials are mixed.

The magnetite powder, the nickel powder and the copper powder are individually ground by using an ultra-fine powder grinding machine to obtain ground magnetite powder, ground nickel powder and ground copper powder. The ground magnetite powder, the ground nickel powder and the ground copper powder are added into a dry powder mixer to obtain a first powder mixture. The graphite powder, the carbon black powder and the barium titanate powder are added to the first powder mixture to thereby obtain a second powder mixture. The second powder mixture is stirred to obtain a mixed wave-absorbing magnetic material. Particle sizes of the magnetite powder, the nickel powder and the copper powder are controlled at 2 μm by using the ultra-fine powder grinding machine.

Step 3, rare earth materials are mixed.

The samarium oxide, the gadolinium oxide and the cerium oxide are dried in a vacuum drying oven to obtain dried samarium oxide, dried gadolinium oxide and dried cerium oxide. The dried samarium oxide, the dried gadolinium oxide and the dried cerium oxide are mixed by the dry powder mixer to obtain a mixed rare earth oxide material. Parameters of the vacuum drying oven include 90° C. of a temperature, and 20 min of a drying duration.

Step 4, the composite electromagnetic wave-absorbing material is prepared.

The epoxy resin and the curing agent are mixed and stirred in a heated environment to obtain a first mixture. A temperature of the heated environment is 60° C. The diluent is added to the first mixture to obtain a second mixture. The second mixture is continuously stirred to obtain a mixed matrix. The mixed wave-absorbing magnetic material prepared in the step 2 and the mixed rare earth oxide material prepared in the step 3 are added to the mixed matrix to thereby obtain a third mixture. The third mixture is stirred for mixing. The antioxidant and the leveling agent are added to the third mixture for ultrasonic dispersion during stirring the third mixture, to thereby obtain the composite electromagnetic wave-absorbing material.

In the embodiment, other parameters of the embodiment are the same as those of embodiment 3.

### Embodiment 3

As illustrated in FIG. 1, a composite electromagnetic wave-absorbing material provided by the embodiment includes the following raw materials in parts by weight: 55 parts of magnetite powder, 7 parts of nickel powder, 7 parts of copper powder, 3 parts of samarium oxide, 3 parts of gadolinium oxide, 3 parts of cerium oxide, 6 parts of carbon black powder, 10 parts of graphite powder, 26 parts of epoxy resin, 6 parts of barium titanate powder, 1 part of antioxidant, 18 parts of curing agent, 1 part of diluent and 1 part of leveling agent. The samarium oxide, the gadolinium oxide, the cerium oxide and the barium titanate powder are all in powder form. The antioxidant is phenolic antioxidant. The curing agent is aromatic amine curing agent diethyl toluene diamine. The diluent is polyol glycidyl ether. The leveling agent is silicone oil. The epoxy resin is bisphenol A based epoxy resins.

A preparation method for the composite electromagnetic wave-absorbing material provided by the embodiment includes the following step 1 through step 4.

Step 1, materials are prepared.

According to a formula, 55 parts of the magnetite powder, 7 parts of the nickel powder, 7 parts of the copper powder, 3 parts of the samarium oxide, 3 parts of the gadolinium oxide, 3 parts of the cerium oxide, 6 parts of the carbon black powder, 10 parts of the graphite powder, 26 parts of the epoxy resin, 6 parts of the barium titanate powder, 1 part of the antioxidant, 18 parts of the curing agent, 1 part of the diluent and 1 part of the leveling agent are weighed.

Step 2, wave-absorbing magnetic materials are mixed.

The magnetite powder, the nickel powder and the copper powder are individually ground by using an ultra-fine powder grinding machine to obtain ground magnetite powder, ground nickel powder and ground copper powder. Particle sizes of the magnetite powder, the nickel powder and the copper powder are controlled at 3 μm by using the ultra-fine powder grinding machine. By reducing particle sizes of these powders to a micron level, specific surface areas of these powders can be increased, thereby enhancing dispersibility of these powders in a composite material and contact areas between these powders and a matrix, and helping to improve electromagnetic performance of the composite material. At the same time, refined powder particles are more easily uniformly dispersed in materials of the matrix, thereby reducing agglomeration phenomena. The ground magnetite powder, the ground nickel powder and the ground copper powder are added into the dry powder mixer to obtain a first powder mixture. The graphite powder, the carbon black powder and the barium titanate powder are added to the first powder mixture to thereby obtain a second powder mixture. The second powder mixture is stirred for 8 min to obtain a mixed wave-absorbing magnetic material.

Step 3, rare earth materials are mixed.

The samarium oxide, the gadolinium oxide and the cerium oxide are dried in a vacuum drying oven to obtain dried samarium oxide, dried gadolinium oxide and dried cerium oxide. Parameters of the vacuum drying oven include 100° C. of a temperature, and 12 min of a drying duration. A purpose of drying is mainly to remove moisture absorbed by the rare earth materials during processes of storage and transportation. The dried samarium oxide, the dried gadolinium oxide and the dried cerium oxide are mixed by the dry powder mixer for 5 min to obtain a mixed rare earth oxide material.

Step 4, the composite electromagnetic wave-absorbing material is prepared.

The epoxy resin and curing agent are mixed and stirred in a heated environment to obtain a first mixture. A temperature of the heated environment is 70° C. In an embodiment, the epoxy resin is added into a mixer, then the mixer is heated to 70° C., and the curing agent is added to the mixer to obtain the first mixture. The mixer is started to mix the first mixture uniformly. The diluent is added to the first mixture to obtain a second mixture. The second mixture is continuously stirred to facilitate dispersion and mixing of fillers, to thereby obtain a mixed matrix. The mixed wave-absorbing magnetic material prepared in the step 2 and the mixed rare earth oxide material prepared in the step 3 are added to the mixed matrix to thereby obtain a third mixture. The third mixture is stirred for mixing for 15 min. The antioxidant and the leveling agent are added to the third mixture during a mixing process of stirring the third mixture to obtain a fourth mixture. The mixing process is a primarily mixing, serving to achieve a pre-dispersion effect. After the mixing process is completed, the fourth mixture is put into an ultrasonic disperser for ultrasonic dispersion. Ultrasonic dispersion technology can be used to help the fillers disperse evenly in the epoxy resin, and the method of primarily mixing can reduce a duration of the ultrasonic dispersion, thereby improving preparation efficiency. After the ultrasonic dispersion is completed, the composite electromagnetic wave-absorbing material is obtained. In an embodiment, the composite electromagnetic wave-absorbing material can be shaped, cured and performed with corresponding post-treatment according to requirements. In the embodiment, a power of the ultrasonic disperser is 1500 watts (W), an ultrasonic frequency is 20 kilohertz (kHz), and an ultrasonic dispersion duration is 30 min.

Combining the embodiment 1, the embodiment 2 and the embodiment 3, in the disclosure, by using the composite electromagnetic wave-absorbing material, the magnetite powder is used as a main body to compound with a small amount of the nickel powder and the copper powder, so that magnetic loss characteristics of the magnetite powder, ferromagnetic behavior of the nickel powder and conductivity of the copper powder are combined, helping to achieve good electromagnetic wave-absorbing performance. By introducing the graphite powder and the carbon black powder as conductive fillers to be added into the wave-absorbing material, conductivity of the wave-absorbing material is improved, so as to improve impedance matching and enhance wave-absorbing effect. The barium titanate powder is a material with high dielectric constant, can improve dielectric loss of the composite material, help the composite material to absorb electromagnetic waves, and meanwhile has good thermal stability. By introducing the rare earth oxides, i.e., doping rear earth, wave-absorbing performance of the composite electromagnetic wave-absorbing material is improved, that is, an absorption volume is improved, a bandwidth is expanded and a matching thickness is reduced. In the disclosure, the epoxy resin is used as an adhesive. As a thermosetting resin, the epoxy resin has strong adhesive ability, and can firmly bond all kinds of fillers in the wave-absorbing material together to form a stable composite material.

The composite electromagnetic wave-absorbing materials provided by the embodiment 1, the embodiment 2 and the embodiment 3 are measured by a vector network analyzer, and compared with a control group (the control group is a common ferrite wave-absorbing material purchased in a market), and test results are shown in Table 1.

TABLE 1

| | embodi- | embodi- | embodi- | control |
|---|---|---|---|---|
| | ment 1 | ment 2 | ment 3 | group |
| first absorption peak | 7.4 | 7.6 | 7.5 | 8.0 |
| (gigahertz abbreviated as GHz) | | | | |
| absorption volume | −26.5 | −27.0 | −26.0 | −13.0 |
| (decibel abbreviated as dB) | | | | |
| second absorption peak (GHz) | 8.3 | 8.4 | 8.5 | 8.9 |
| absorption volume(dB) | −27.5 | −28.2 | −26.9 | −17.5 |
| matching thickness (millimeter | 1.05 | 1.02 | 1.03 | 1.14 |
| abbreviated as mm) | | | | |
| 10 dB bandwidth (GHz) | 1.9 | 2.0 | 1.8 | 1.0 |

As shown in above table, the composite electromagnetic wave-absorbing material provided by the disclosure has a better wave-absorbing performance.

Above contents show and describe basic principles, main features and advantages of the disclosure. Those skilled in the art should understand that, the disclosure is not limited by embodiments described above. The embodiments described above and specification are merely used to illustrate the basic principles of the disclosure. Modification and improvement made to the disclosure without departing from a framework and an application scope of the disclosure shall fall within the scope of protection of the disclosure. The scope of protection of the disclosure is claimed by the claims and its equivalent.

What is claimed is:

1. A composite electromagnetic wave-absorbing material, comprising the following raw materials in parts by weight: 50-60 parts of magnetite powder, 5-8 parts of nickel powder, 5-8 parts of copper powder, 2-4 parts of samarium oxide, 2-4 parts of gadolinium oxide, 2-4 parts of cerium oxide, 5-7 parts of carbon black powder, 8-15 parts of graphite powder, 20-30 parts of epoxy resin, 5-7 parts of barium titanate powder, 1-2 parts of antioxidant, 15-20 parts of curing agent, 1-2 parts of diluent and 1-2 parts of leveling agent; wherein the samarium oxide, the gadolinium oxide, the cerium oxide and the barium titanate powder are all in powder form; the antioxidant is a phenolic antioxidant; the curing agent is an aromatic amine curing agent diethyl toluene diamine; the diluent is polyol glycidyl ether; the leveling agent is silicone oil; and the epoxy resin is bisphenol A based epoxy resin.

2. The composite electromagnetic wave-absorbing material as claimed in claim 1, comprising the following raw materials in parts by weight: 60 parts of the magnetite powder, 5 parts of the nickel powder, 5 parts of the copper powder, 2 parts of the samarium oxide, 2 parts of the gadolinium oxide, 2 parts of the cerium oxide, 7 parts of the carbon black powder, 8 parts of the graphite powder, 20 parts of the epoxy resin, 7 parts of the barium titanate powder, 2 parts of the antioxidant, 15 parts of the curing agent, 2 parts of the diluent and 2 parts of the leveling agent.

3. The composite electromagnetic wave-absorbing material as claimed in claim 1, comprising the following raw materials in parts by weight: 50 parts of the magnetite powder, 8 the parts of nickel powder, 8 parts of the copper powder, 4 parts of the samarium oxide, 4 parts of the gadolinium oxide, 4 parts of the cerium oxide, 5 parts of the carbon black powder, 15 parts of the graphite powder, 30 parts of the epoxy resin, 5 parts of the barium titanate powder, 1 part of the antioxidant, 20 parts of the curing agent, 1 part of the diluent and 1 part of the leveling agent.

4. A preparation method for the composite electromagnetic wave-absorbing material as claimed in claim 1, comprising the following steps:
step 1, preparing materials, comprising:
weighing, according to a formula, 50-60 parts of the magnetite powder, 5-8 parts of the nickel powder, 5-8 parts of the copper powder, 2-4 parts of the samarium oxide, 2-4 parts of the gadolinium oxide, 2-4 parts of the cerium oxide, 5-7 parts of the carbon black powder, 8-15 parts of the graphite powder, 20-30 parts of the epoxy resin, 5-7 parts of the barium titanate powder, 1-2 parts of the antioxidant, 15-20 parts of the curing agent, 1-2 parts of the diluent and 1-2 parts of the leveling agent;
step 2, mixing wave-absorbing magnetic materials, comprising:
grinding the magnetite powder, the nickel powder and the copper powder to obtain a first powder mixture, adding the graphite powder, the carbon black powder and the barium titanate powder to the first powder mixture to thereby obtain a second powder mixture, and stirring the second powder mixture to obtain a mixed wave-absorbing magnetic material;
step 3, mixing rare earth materials, comprising:
drying the samarium oxide, the gadolinium oxide and the cerium oxide to obtain dried samarium oxide, dried gadolinium oxide and dried cerium oxide, and mixing the dried samarium oxide, the dried gadolinium oxide and the dried cerium oxide to obtain a mixed rare earth oxide material; and
step 4, preparing the composite electromagnetic wave-absorbing material, comprising:
stirring and mixing the epoxy resin and the curing agent in a heated environment to obtain a first mixture, adding the diluent to the first mixture to obtain a second mixture, continuing to stir the second mixture to obtain a mixed matrix, adding the mixed wave-absorbing magnetic material prepared in the step 2 and the mixed rare earth oxide material prepared in the step 3 to the mixed matrix to thereby obtain a third mixture, stirring the third mixture for mixing, and adding the antioxidant and the leveling agent to the third mixture for ultrasonic dispersion during stirring the third mixture, to thereby obtain the composite electromagnetic wave-absorbing material.

5. The preparation method for the composite electromagnetic wave-absorbing material as claimed in claim 4, wherein, in the step 2, particle sizes of the magnetite powder, the nickel powder and the copper powder are controlled in a range of 2 micrometers (μm) to 5 μm by using a powder grinding machine.

6. The preparation method for the composite electromagnetic wave-absorbing material as claimed in claim 4, wherein, in the step 3, the samarium oxide, the gadolinium oxide and the cerium oxide are dried by vacuum drying at a temperature in a range of 90 Celsius degrees (° C.) to 120° C. for 10 minutes (min) to 20 min.

7. The preparation method for the composite electromagnetic wave-absorbing material as claimed in claim 4, wherein, in the step 4, a temperature of the heated environment is in a range of 60° C. to 80° C.
